(19) United States
(12) Patent Application Publication
(10) Pub. No.: US 2026/0201546 A1
(43) Pub. Date: Jul. 16, 2026

(54) METHOD FOR FORMING CARBON FILM ON SUBSTRATE

(71) Applicant: Skytech Inc., Hsinchu County (TW)

(72) Inventors: YAO-SYUAN CHENG, Hsinchu County (TW); CHUN-FU WANG, Hsinchu County (TW); KUO-JU LIU, Hsinchu County (TW); CHING-LIANG YI, Hsinchu County (TW)

(21) Appl. No.: 19/176,064

(22) Filed: Apr. 10, 2025

(30) Foreign Application Priority Data
Jan. 15, 2025 (TW) 114101665

(51) Int. Cl. C23C 16/04; C23C 14/48; C23C 16/02; C23C 16/26; C23C 16/56

(52) U.S. Cl. CPC C23C 16/04; C23C 14/48; C23C 16/0245; C23C 16/26; C23C 16/56

(57) ABSTRACT

This disclosure is a method for forming a carbon film on a substrate, and comprises: performing an ion implantation process on a substrate to form an ion-implanted region on a surface of the substrate; heating the substrate and performing a plasma pre-cleaning process on the substrate; forming a carbon film on the surface of the substrate; and then annealing the substrate at a high temperature. After performing the heating process and the plasma pre-cleaning process, moisture and dangling bonds on the substrate can be removed, which is conducive to forming a dense and smooth carbon film on the substrate to improve the protective effect of the carbon film on the substrate.

### CROSS-REFERENCE TO RELATED APPLICATIONS

This non-provisional application claims priority claim under 35 U.S.C. §119(a) on Taiwan Patent Application No. 114101665 filed January 15, 2025, the entire contents of which are incorporated herein by reference.

### TECHNICAL FIELD

This disclosure relates to a method for forming a carbon film on a substrate, which is able to improve the structural strength and smoothness of the carbon film.

### BACKGROUND

Depending on the material, semiconductor materials can be classified into first-generation, second-generation, and third-generation semiconductor materials, each suited for different technological fields and products.

First-generation semiconductor materials include germanium (Ge) and silicon (Si). These are the most mature semiconductor materials in terms of process technology and are also the most widely used. They are widely applied in the information and electronics industries.

Second-generation semiconductor materials include gallium arsenide (GaAs) and indium phosphide (InP). Compared with first-generation semiconductor materials, second-generation semiconductor materials have advantages such as faster electron mobility and excellent high-frequency characteristics. They are widely used in the communication devices, microwave components, and lighting industries.

Third-generation semiconductors are represented by silicon carbide (SiC) and gallium nitride (GaN). Compared to first and second-generation semiconductor materials, third-generation semiconductor materials have advantages such as a wide band gap, high-temperature resistance, high-voltage resistance, and higher energy conversion efficiency. Therefore, they are widely used in emerging industries such as chargers, electric vehicles, 5G communications, and artificial intelligence, making third-generation semiconductors the new favorites of the semiconductor industry.

SiC and GaN each have their own advantages. Among them, SiC has the advantages of a wider band gap, higher thermal conductivity, and high electron saturation velocity, while GaN has the advantages of high electron mobility, low noise, and better high-frequency characteristics.

When fabricating semiconductor devices using SiC, a process of epitaxy and ion implantation is typically performed on the SiC substrate to form an ion-implanted region on a portion of the SiC substrate. After completing the ion implantation process, the SiC substrate undergoes high-temperature annealing to allow the implanted ions to diffuse and become activated.

The high temperature during annealing may cause silicon sublimation in the SiC substrate, resulting in a rough surface and the formation of step bunching of the substrate. The impact on the ion-implanted region is even greater. Step bunching will degrade the interface properties of Schottky contacts and FET channels.

### SUMMARY

In order to avoid the problems described in the prior art, this invention provides a method for forming a carbon film on a substrate. The main process involves pre-treating the substrate to remove moisture and perform plasma cleaning process before forming the carbon film on the substrate. This is advantageous for forming a dense and smooth carbon film on the substrate and can prevent the surface of the substrate from becoming rough or forming step bunching during the high-temperature annealing process.

One object of the invention is to provide a method for forming a carbon film on a substrate. After performing the ion implantation process on the substrate, the substrate is heated to remove moisture on or within the substrate. This can prevent moisture from existing between the subsequently formed carbon film and the substrate. If moisture exists between the substrate and the carbon film, the moisture will be affected by high temperature during high-temperature annealing, resulting in damage to the carbon film or the formation of gaps between the carbon film and the substrate.

One object of the invention is to provide a method for forming a carbon film on a substrate. After performing the ion implantation process on the substrate, a plasma pre-cleaning process can be performed on the substrate to remove dangling bonds on the surface of the substrate. This can prevent the dangling bonds on the substrate surface from interacting with the subsequently formed carbon film, which could lead to a looser structure of the carbon film and reduce the effect of the carbon film protecting the substrate.

To achieve the foregoing objectives, this disclosure provides a method for forming a carbon film on a substrate, comprising: performing an ion implantation process on a substrate to form at least one ion-implanted region on the substrate; performing a heating process on the substrate to remove moisture from the substrate; performing a plasma pre-cleaning process on the substrate; forming a carbon film on at least one surface of the substrate, wherein the carbon film covers the ion-implanted region on the substrate; and performing a high-temperature annealing process on the substrate.

This disclosure provides another method for forming a carbon film on a substrate, comprising: performing an ion implantation process on a substrate to form at least one ion-implanted region on the substrate; performing a heating process on the substrate to remove moisture from the substrate; forming a carbon film on at least one surface of the substrate, wherein the carbon film covers the ion-implanted region on the substrate; and performing a high-temperature annealing process on the substrate.

This disclosure further provides another method for forming a carbon film on a substrate, comprising: performing an ion implantation process on a substrate to form at least one ion-implanted region on the substrate; performing a plasma pre-cleaning process on the substrate; forming a carbon film on at least one surface of the substrate, wherein the carbon film covers the ion-implanted region on the substrate; and performing a high-temperature annealing process on the substrate.

### BRIEF DESCRIPTION OF THE DRAWINGS

FIG. 1 is a flowchart of a method for forming a carbon film on a substrate according to an embodiment of the invention.

FIG. 2 is a cross-sectional view of an ion-implanted substrate according to an embodiment of the invention.

FIG. 3 is a cross-sectional view of a substrate with a carbon film according to an embodiment of the invention.

### DETAILED DESCRIPTION

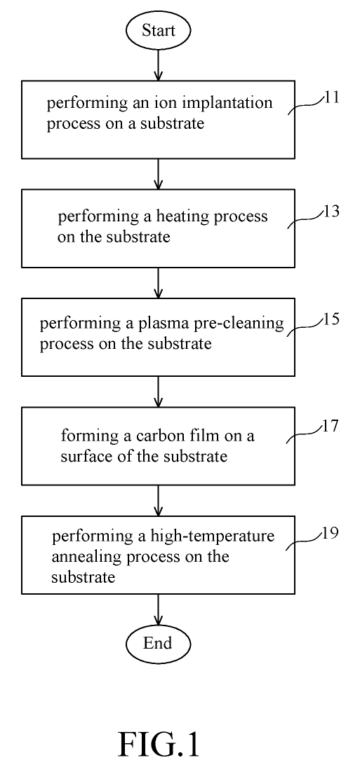

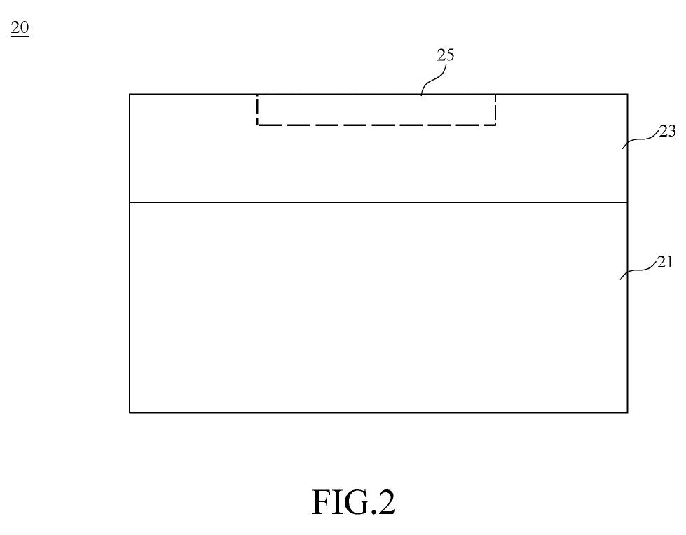

FIG. 1 is a flowchart of a method for forming a carbon film on a substrate according to an embodiment of the invention. FIG. 2 is a cross-sectional view of an ion-implanted substrate according to an embodiment of the invention. A substrate 20 is first provided. In one embodiment of the invention, the substrate 20 may be an epitaxially grown substrate, and includes a silicon carbide (SiC) substrate 21 and an epitaxial layer 23. In practical applications, an epitaxy process may be performed on the SiC substrate 21, such as chemical vapor deposition (CVD), molecular beam epitaxy (MBE), liquid phase epitaxy (LPE), or solid phase epitaxy (SPE), etc., to form the epitaxial layer 23 on the SiC substrate 21. The epitaxy method is not the main technical feature of the invention, nor is it a limitation of the scope of the invention.

The substrate 20 undergoes an ion implantation process to form at least one ion-implanted region 25 on at least one surface of the substrate 20, wherein the ion-implanted region 25 is located on the epitaxial layer 23, as shown in step 11

In practical applications, photoresist can be formed on portions surface of the epitaxial layer 23 of the substrate 20 through lithography processes, wherein the photoresist can be used to block the implanted ions to form ion-implanted regions 25 in portions of the epitaxial layer 23.

The ion source may include nitrogen, phosphorus, arsenic, inert gases, etc. For example, n-type doping may be formed through nitrogen or phosphorus, and p-type doping may be formed through aluminum or boron.

In one embodiment of the invention, the SiC substrate 21 and the epitaxial layer 23 may be n-type semiconductors. For example, the SiC substrate 21 may be an n+ type semiconductor, and the epitaxial layer 23 may be an n- type semiconductor, and the ion-implanted region 25 formed on the epitaxial layer 23 may be a p-type semiconductor.

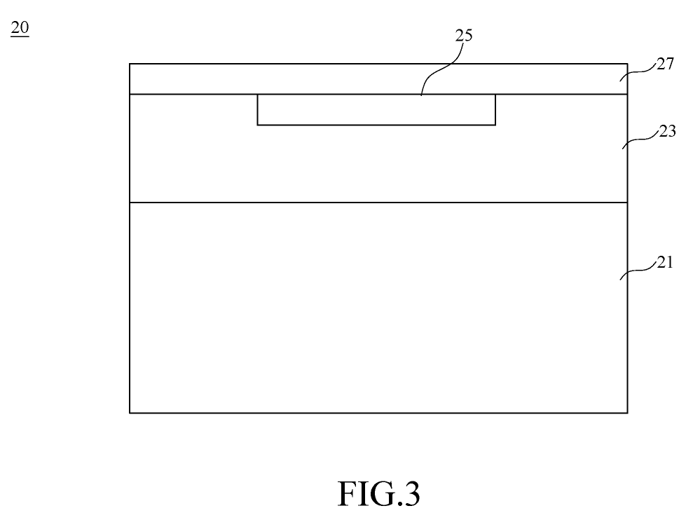

For the convenience of explanation, only one ion-implanted region 25 is drawn on the epitaxial layer 23 in FIG. 2 and FIG. 3 of the invention. In practical applications, a plurality of ion-implanted regions 25 may be formed on the epitaxial layer 23. In addition, further ion implantation process may be performed on the ion-implanted region 25 to form different types of semiconductors within the ion-implanted region 25. For example, the ion-implanted region 25 on the epitaxial layer 23 is a p-type semiconductor, and n+ type semiconductors or p+ type semiconductors can be formed within the ion-implanted region 25.

Specifically, the area, size, number, and type of the ion-implanted regions 25 are not the main features of the invention, nor are they limitations of the scope of the claims of the invention.

After the ion implantation process is completed on the substrate 20, it often causes lattice defects and impurities in the substrate 20. These defects or impurities may affect the performance of subsequently manufactured electronic products or chips. Therefore, after completing the ion implantation process, a high-temperature annealing process is required to repair these defects and activate the implanted ions to improve the performance of subsequently manufactured electronic products or chips.

Generally speaking, the annealing temperature of the substrate 20 is controlled between about 1200°C and 1800°C. During the high-temperature annealing process, the surface of the SiC substrate 20 will experience silicon sublimation due to the high temperature, resulting in step bunching on the surface of the substrate 20. The impact on the ion-implanted region 25 may be even more severe. Step bunching will cause a decrease in the mobility of electrons in the channel and lead to deterioration of the interface properties of Schottky contacts and FET channels.

To solve the above-mentioned problems, a carbon film 27 is formed on the surface of the substrate 20 before high-temperature annealing process is performed. The carbon film 27 can be used to protect the substrate 20 to avoid the formation of step bunching on the surface of the substrate 20 after high-temperature annealing, and to improve the roughness of the surface of the ion-implanted region 25 of the substrate 20.

Although the provision of the carbon film 27 can initially solve the problems encountered in the prior art, the carbon film 27 formed on the surface of the substrate 20 through general manufacturing methods often has problems of insufficient structural density and insufficient surface smoothness. The carbon film 27 with insufficient structural density cannot provide good protection to the substrate 20, causing the substrate 20 to still have surface roughness problems after high-temperature annealing process.

One of possible reasons for this is that there may be gases or impure substances remaining from previous processes on the surface or inside the substrate 20, and the carbon film 27 formed on the surface of the substrate 20 will cover these gases or impure substances.

When the substrate 20 is subjected to high-temperature annealing process, the gas or impure substances covered by the carbon film 27 may be affected by the high temperature and diffuse outward in the direction of the carbon film 27, thereby damaging the structure of the carbon film 27, resulting in a decrease in the adhesion between the substrate 20 and the carbon film 27, and generating gaps between the substrate 20 and the carbon film 27. Especially when the temperature of the high-temperature annealing process is greater than 1900°C or 2000°C, it is more likely to cause structural damage to the carbon film 27 or form gaps between the substrate 20 and the carbon film 27.

When the structure of the carbon film 27 is damaged, it may cause some areas of the substrate 20 to come into contact with the outside, and cause silicon sublimation to occur on the exposed surface of the substrate 20, so that the surface of the substrate 20 may still form step bunching.

Furthermore, when there are gaps between the substrate 20 and the carbon film 27, these gaps provide space for silicon sublimation of the substrate 20, which will also form a rough surface on the substrate 20.

To address the above-mentioned problems, this invention further proposes a method for forming the carbon film 27 on the surface of the substrate 20. The main process involves pre-heating the substrate 20 to remove moisture on or within the substrate 20, either before forming the carbon film 27 on the surface of the substrate 20, or after the ion implantation process is completed on the substrate 20, as shown in step 13.

In one embodiment of the invention, the substrate 20 may be placed in a high-temperature environment for baking. The heating temperature of the substrate 20 may be between 100°C and 300°C. For example, the substrate 20 may be placed in the environment of 100°C to 300°C for 60 seconds to 300 seconds to remove moisture from the substrate 20. The above-mentioned baking temperature and baking time are only one embodiment of the invention, and are not limitations of the scope of the claims of the invention.

After completing the heating process of the substrate 20, a plasma pre-cleaning process can be further performed on the substrate 20, as shown in step 15. For example, the plasma pre-cleaning process may be performed on the substrate 20 through argon plasma, hydrogen plasma, helium plasma, neon plasma, or nitrogen plasma.

In general, before the carbon film 27 is formed on the surface of the substrate 20, the surface of the substrate 20 may have dangling bonds due to previous processes. These dangling bonds may interact with the carbon film 27 subsequently formed on the surface of the substrate 20, resulting in a loosely structured material.

The loosely structured carbon film 27 may be damaged during the high-temperature annealing process, causing some areas of the substrate 20 to come into contact with the outside, and causing silicon sublimation to occur on the exposed surface of the substrate 20, and step bunching is formed on the surface of the substrate 20. In addition, there may be gaps between the loosely structured carbon film 27 and the substrate 20. These gaps will provide space for silicon sublimation of the substrate 20, and will also form a rough surface on the substrate 20.

After completing the above heating process and the plasma pre-cleaning process, the carbon film 27 can be formed on the surface of the substrate 20, as shown in step 17 and FIG. 3. For example, the carbon film 27 may be formed on the surface of substrate 20, which includes the epitaxial layer 23 and/or the ion-implanted region 25, so that the carbon film 27 completely covers the surface of the ion-implanted region 25 and/or the surface of the epitaxial layer 23 where the ion-implanted region 25 is provided. In other embodiments, the carbon film 27 may also be formed on the surface of the substrate 20 where the ion-implanted region 25 is not provided. For example, the carbon film 27 is formed on the surface of the epitaxial layer 23 and the SiC substrate 21 of the substrate 20.

After forming the carbon film 27 on the surface of the substrate 20, the high-temperature annealing process is performed on the substrate 20, as shown in step 19.

Because the substrate 20 is baked and plasma pre-cleaned before the carbon film 27 is formed on the substrate 20, after the carbon film 27 is formed on the substrate 20, the moisture or foreign substances existing between the carbon film 27 and the substrate 20 can be greatly reduced, and the dangling bonds on the surface of the substrate 20 can be reduced, which can prevent the carbon film 27 from being damaged during the high-temperature annealing process, and is beneficial to improve the protective effect of the carbon film 27 on the substrate 20.

According to the results of experimental tests, when the substrate 20 is not subjected to the heating process and the plasma pre-cleaning process, the smooth carbon film 27 may be formed on the surface of the substrate 20. For example, the arithmetic mean roughness Ra of the surface of the carbon film 27 may be less than 1nm. However, the substrate 20 without the heating process and the plasma pre-cleaning process, after the high-temperature annealing process, for example, when the temperature of high-temperature annealing process is greater than 1800°C or 1900°C, the arithmetic mean roughness Ra of the surface of the carbon film 27 will be greater than 1nm.

In other words, the carbon film 27 on the surface of the substrate 20, without the heating process and the plasma pre-cleaning process, may have its structure deteriorated after the high-temperature annealing process, and form an uneven surface, which cannot provide good protection to the substrate 20.

In contrast, after the substrate 20 undergoes the heating process and the plasma pre-cleaning process described in the invention, the arithmetic mean roughness Ra of the carbon film 27 on the surface of the substrate 20 before the high-temperature annealing process will be less than 1nm. In addition, after the substrate 20 is subjected to high-temperature annealing process, for example, when the temperature of high-temperature annealing process is 1900°C to 2000°C, the arithmetic mean roughness Ra of the carbon film 27 on the surface of the substrate 20 will still be less than 1nm. In other words, through the method described in the invention, the structural deterioration of the carbon film 27 on the surface of the substrate 20 can be effectively prevented, wherein the carbon film 27 can still maintain the smooth surface after high-temperature annealing process, and provide good protection to the substrate 20.

In one embodiment of the invention, the substrate 20 may be transported to a CVD chamber, and the carbon film 27 is formed on the surface of the substrate 20 through the CVD process in the CVD chamber. In this way, after the substrate 20 is transported to the CVD chamber, the substrate 20 can be directly heated by the heating device in the CVD chamber. For example, the heating temperature of the substrate 20 is 100°C to 300°C, and the heating time is 60 seconds to 300 seconds. Then the plasma pre-cleaning process is performed on the substrate 20 in the CVD chamber through plasma. After completing the heating process and plasma pre-treatment process of the substrate 20 in the CVD chamber, the CVD process can be performed on the substrate 20 to form the carbon film 27 on the surface of the substrate 20.

In other embodiments, the substrate 20 may be heating and subjected to the plasma pre-cleaning process in a separate chamber. After completing the heating process and the plasma pre-cleaning process of the substrate 20, the substrate 20 is transferred to the CVD chamber to form the carbon film 27 on the surface of the substrate 20 through the CVD process.

Because the substrate 20 of the invention undergoes the heating process and the plasma pre-cleaning process, the carbon film 27 provided on the surface of the substrate 20 can maintain structural stability during the high-temperature annealing process, so as to provide better protection to the substrate 20.

In addition, through the method described in the invention, the annealing temperature or annealing time of the substrate 20 may be increased as needed to greatly improve the diffusion and activation effect of the implanted ions without forming uneven step bunching on the surface of the substrate 20. For example, the annealing temperature may be greater than 1900°C.

After high-temperature annealing process, the ions in the ion-implanted region 25 can be activated, and n-type or p-type well regions can be formed on the epitaxial layer 23 of the substrate 20.

After completing the high-temperature annealing process, the carbon film 27 on the surface of the substrate 20 can be removed, and the substrate 20 can be subjected to subsequent processes.

In the above embodiments of the invention, the substrate 20 is heated first, and then the plasma pre-cleaning process is performed on the substrate 20. In other embodiments, the plasma pre-cleaning process may be performed on the substrate 20 first, and then the substrate 20 is heated.

In addition, in another embodiment of the invention, the substrate 20 may be heated only, and then the carbon film 27 is formed on at least one surface of the heated substrate 20. Or, only the plasma pre-cleaning process is performed on the substrate 20, and then the carbon film 27 is formed on at least one surface of the substrate 20 after the plasma pre-cleaning process. Of course, the carbon film 27 formed on the substrate 20 after the heating process and the plasma pre-cleaning process can provide better protection to the substrate 20. However, the carbon film 27 formed on the substrate 20 after only performing the heating process or the plasma pre-cleaning process can still provide better protection to the substrate 20 compared with the prior art, so that the substrate 20 can still maintain a relatively smooth surface after the high-temperature annealing process.

In summary, before forming the carbon film 27 on the surface of the substrate 20, the invention heats the substrate 20 to remove moisture, and performs the plasma pre-cleaning process on the substrate 20 to remove dangling bonds on the surface of the substrate 20. This can greatly improve the structural strength and surface smoothness of the carbon film 27, so that the carbon film 27 can provide better protection to the substrate 20 during the high-temperature annealing process, and is also beneficial to increasing the temperature and time of the high-temperature annealing process to improve the activation effect of the implanted ions.

The foregoing descriptions are merely preferred embodiments of this disclosure, and are not intended to limit the scope of this disclosure, that is, all equivalent changes and modifications made according to shapes, structures, features and spirits described in the scope of the claims of this disclosure shall fall within the scope of the claims of this disclosure.

What is claimed is:

1. A method for forming a carbon film on a substrate, comprising:
performing an ion implantation process on a substrate to form at least one ion-implanted region on the substrate;
performing a heating process on the substrate to remove moisture from the substrate;
performing a plasma pre-cleaning process on the substrate;
forming a carbon film on at least one surface of the substrate, wherein the carbon film covers the ion-implanted region on the substrate; and
performing a high-temperature annealing process on the substrate.

2. The method as claimed in claim 1, further comprising: performing the heating process on the substrate to between 100°C and 300°C.

3. The method as claimed in claim 2, further comprising: performing the heating process on the substrate for 60 seconds to 300 seconds.

4. The method as claimed in claim 1, wherein the substrate comprising a SiC substrate and an epitaxial layer, and the ion-implanted region is located on the epitaxial layer.

5. The method as claimed in claim 1, further comprising: performing the high-temperature annealing process of the substrate at a temperature above 1900°C.

6. The method as claimed in claim 1, further comprising:
transporting the substrate to a chemical vapor deposition chamber;
performing the heating process and the plasma pre-cleaning process of the substrate within the chemical vapor deposition chamber; and
forming the carbon film on the at least one surface of the substrate via a chemical vapor deposition process within the chemical vapor deposition chamber.

7. The method as claimed in claim 1, further comprising:
transporting the substrate to a chemical vapor deposition chamber, after performing the heating process and the plasma pre-cleaning process of the substrate; and
forming the carbon film on the at least one surface of the substrate via a chemical vapor deposition process within the chemical vapor deposition chamber.

8. A method for forming a carbon film on a substrate, comprising:
performing an ion implantation process on a substrate to form at least one ion-implanted region on the substrate;
performing a heating process on the substrate to remove moisture from the substrate;
forming a carbon film on at least one surface of the substrate, wherein the carbon film covers the ion-implanted region on the substrate; and
performing a high-temperature annealing process on the substrate.

9. The method as claimed in claim 8, further comprising: performing the heating process on the substrate to between 100°C and 300°C.

10. A method for forming a carbon film on a substrate, comprising:
performing an ion implantation process on a substrate to form at least one ion-implanted region on the substrate;
performing a plasma pre-cleaning process on the substrate;
forming a carbon film on at least one surface of the substrate, wherein the carbon film covers the ion-implanted region on the substrate; and
performing a high-temperature annealing process on the substrate.
